(19) United States
(12) Patent Application Publication
(10) Pub. No.: US 2016/0010207 A1
(43) Pub. Date: Jan. 14, 2016

(54) Plasma-Enhanced Atomic-Layer Deposition System and Method

(71) Applicant: Dongjun WANG, (US)

(72) Inventor: Dongjun Wang, Beijing (CN)

(21) Appl. No.: 14/648,700

(22) PCT Filed: Apr. 3, 2013
(86) PCT No.: PCT/CN2013/073761

§ 371 Date: May 30, 2015

(51) Int. Cl. C23C 16/44; C23C 16/458; C23C 16/455

(52) U.S. Cl. CPC C23C 16/4412; C23C 16/45544; C23C 16/45565; C23C 16/45559; C23C 16/4586; C23C 16/45536

(57) ABSTRACT

In one example, we describe a type of plasma-enhanced atomic layer deposition equipment including: fluidly connected plasma generation chamber, diffusion chamber, reaction chamber, and pumping chamber, wherein the plasma generation chamber includes a plasma generation gas inlet and a plasma generation device that enables the generation of plasma from the plasma generation gas coming from the plasma generation gas inlet. A precursor inlet is disposed between the plasma generation chamber and the diffusion chamber. Precursors coming from the precursor inlet and generated plasma diffuse uniformly inside the diffusion chamber. A sample stage, for the placement of sample to be deposited on, is disposed inside the reaction chamber. The pumping chamber is sequentially connected to an exhaust trap and pumping system. The equipment has enabled high quality atomic layer thin film deposition.

### RELATED APPLICATION

This current application is based on a PCT case, PCT/CN2013/073761, filed in China, on 3 Apr. 2013, whose teachings are incorporated herein by reference, and it also claims priority date of that PCT case.

### FIELD OF INVENTION

This invention relates to one type of atomic layer deposition equipment, and more specifically, to one type of plasma-enhanced atomic layer deposition equipment.

### BACKGROUND OF THE INVENTION

Atomic layer deposition (ALD), also known as atomic layer epitaxy, is a thin film deposition technique first proposed by Finnish scientists for preparation of polycrystalline photoluminescence ZnS:Mn films and amorphous Al₂O₃ films for the application in flat panel displays. Up until the late 1980s, this thin film technique had not seen material breakthrough, due to complicated surface chemistry involved and very low deposition rate.

However, since the mid-1990s, interest in this technique has been steadily growing. Progress in microelectronics and deep submicron chips led to continued reduction in the dimension of semiconductor components and device structures. As a result, growing ultrathin films of a few nanometers, and with good coverage in very high aspect ratio structures in those semiconductor components, has become all the more important. ALD has demonstrated significant advantage in such applications with precise growth rate control at atomic layer level, as well as excellent uniformity and conformality over a large substrate area. Low deposition rate has become less of an issue.

Currently, most ALD systems provide only a heated low vacuum environment, in which, precursors (mostly metal-organics) chemically react to form a thin film on a substrate. Such a chemical reaction is a thermally activated process. Some precursors require high activation energy, which often requires very high heating temperature in such an ALD process. In many cases, high heating temperature may cause precursor decomposition and/or desorption from the substrate, which prevents the reaction to occur, or leads to degraded film quality with high impurity content. Some substrates, particularly those from organic compounds, cannot withstand high temperature, limiting the applicability of purely thermally activated ALD chemistries.

### SUMMARY OF THE INVENTION

This invention provides a plasma-enhanced atomic layer deposition system to realize high quality films deposited by atomic layer deposition. For this purpose, the invention discloses a type of plasma-enhanced atomic layer deposition equipment, including fluidly connected plasma generation chamber, diffusion chamber, reaction chamber, and pumping chamber, wherein the plasma generation chamber comprises one or more plasma generation gas inlets and one or more plasma generation devices, which generate plasma with the plasma generation gas from the plasma generation gas inlet.

There are one or more precursor inlets located between the plasma generation chamber and the diffusion chamber. In the diffusion chamber, precursor(s) from the precursor inlet and the plasma generated in the plasma generation chamber diffuse uniformly. Inside the reaction chamber, a sample stage is set up for placement of sample(s), on the surface of which precursors react to form a thin film.

The pumping chamber is connected sequentially with an exhaust trap and a pumping system. In one embodiment, the plasma generation device is an inductively coupled plasma generation device. In one embodiment, the equipment can include a shower-head component, which contains multiple diffusion holes. The plasma generation gas inlet, the diffusion holes, and the plasma generation chamber are fluidly connected, allowing plasma generation gas to flow through diffusion holes into the plasma generation chamber.

In one embodiment, the equipment can also include an annular multi-hole component installed onto the diffusion chamber. The annular multi-hole component contains multiple diffusion holes, which allow gases to flow from the precursor inlet to the diffusion chamber. In one embodiment, the vertical distance between the top surface of the sample stage and the top of the reaction chamber can be greater than 200 mm.

In one embodiment, the sample stage can be made from stainless steel or pure nickel. In one embodiment, the equipment can include heating elements to heat up the sample stage. In one embodiment, the equipment can also include a sample tray. In one embodiment, the sample tray can be made from pure nickel with a thickness of 2-5 mm. In one embodiment, the sample tray can be fixated onto the sample stage with the clamping slots.

In one embodiment, the ratio of the diameter of the sample tray to the inner diameter of the reaction chamber can be between 1:1.2 to 1:2 range. In one embodiment, the diffusion chamber can be shaped as a dome to enable uniform diffusion of the precursors and generated plasma. In one embodiment, rubber or oxygen-free copper gaskets can be used to seal the connections between the pumping chamber, the reaction chamber, the diffusion chamber, and the plasma generation chamber.

In one embodiment, the pumping chamber, the reaction chamber, the diffusion chamber, and the plasma generation chamber, together, form a spindle-shaped chamber. In one embodiment, the inner diameter of the plasma generation gas inlet can be 2-12 mm. The inner diameter of the diffusion holes in the shower-head component can be 0.2-3 mm.

In one embodiment, the inner diameter of the precursor inlet can be 2 to 12 mm. The inner diameter of the diffusion holes in the annular multi-hole component can be 0.2 to 4 mm. In one embodiment, the pumping system can include a vacuum gauge, a by-pass valve, a throttle valve, a high vacuum valve, a turbo-molecular pump, a foreline valve, and a mechanical pump.

Based on the plasma-enhanced atomic layer deposition equipment in this invention, this invention also discloses a plasma-enhanced atomic layer deposition method. This method includes uniformly distributing generated plasma and precursors on the sample surface. With the energy provided by the plasma, precursors deposit on the sample surface and react to form a thin film.

In one embodiment, the method can also include heating the sample to be deposited on, so as to provide necessary energy for the reaction to form a thin film. In one embodiment, the method can also include removing excess precursors and reaction by-products. Compared to the currently available techniques, the plasma-enhanced atomic layer deposition equipment in this invention utilizes reaction energy provided by plasma, to avoid precursor decomposition and desorption caused by excessively high heating temperature, to ensure an uncompromised chemical reaction process.

Also, reaction temperature can be lowered. Many materials can be deposited only with the energy provided by the plasma and without heating. In addition, uniform distribution of plasma and precursors on the surface of the sample leads to excellent uniformity in the deposited thin film. Furthermore, the plasma is generated with remote inductively-coupled plasma generation. The plasma energy arriving at the substrate surface is mild enough to prevent etching the thin film, leading to high film quality.

### BRIEF DESCRIPTION OF THE DRAWINGS

FIG. 1 is the partial mechanical drawing of the plasma-enhanced atomic layer deposition equipment in this invention.

FIG. 2 is the system diagram of the plasma-enhanced atomic layer deposition equipment in this invention.

FIG. 3A is the detailed view of assembly drawing of the plasma generation gas inlet for the plasma-enhanced atomic layer deposition equipment in this invention.

FIG. 3B is the vertical view of the structure in FIG. 3A.

FIG. 3C is the cross-section view of the structure in FIG. 3A.

FIG. 4A is the detailed view of assembly drawing of the precursor inlet for the plasma-enhanced atomic layer deposition equipment in this invention.

FIG. 4B is the cross-section view of the structure in FIG. 4A.

### REFERENCE NUMBERS TO FEATURES IN THE FIGURES

1: Plasma generation chamber
10: Plasma generation gas inlet
11: Coil
12: Precursor inlet
13: Diffusion hole
14: Annular hole
15: through-hole
16: Diffusion hole
17: Precursor outlet
2: Diffusion chamber
3: Reaction chamber
31: Sample stage
32: Sample tray
33: Heating element
34: Vacuum flange
4: Pumping chamber
5: Exhaust trap
51: Vacuum gauge
52: By-pass valve
53: Throttle valve
54: High-vacuum valve
55: Turbo-molecular pump
56: Foreline valve
57: Mechanical pump
60: Precursor
61: Carrier gas
62: Plasma generation gas
63: Mass flow controller
64: Plasma generation gas inlet
65: Precursor inlet
d: Height

### DETAILED DESCRIPTION OF THE PREFERRED EMBODIMENTS

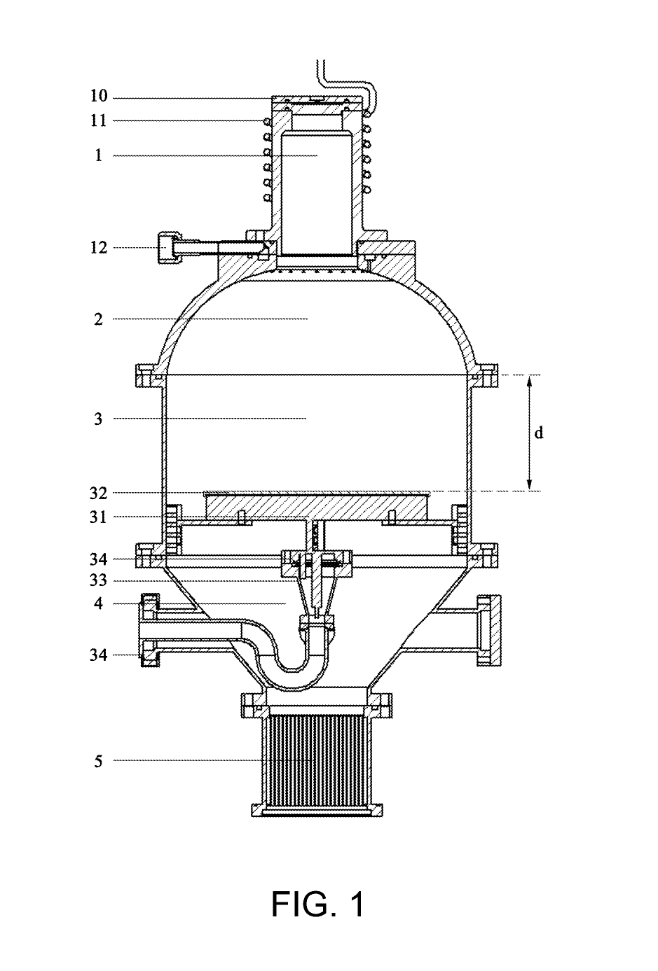

The content and detailed description of this invention are explained with illustration of the attached figures: As shown in FIG. 1, this invention discloses a type of plasma-enhanced atomic layer deposition equipment, including fluidly connected plasma generation chamber 1, diffusion chamber 2, reaction chamber 3, and pumping chamber 4, of which plasma generation chamber 1 consists of a plasma generation gas inlet(s) 10 and a plasma generation device(s), that generates plasma using the plasma generation gas coming from plasma generation gas inlet 10. A precursor inlet(s) 12 is located between the plasma generation chamber 1 and the diffusion chamber 2. Precursors coming from the precursor inlet 12 and generated plasma diffuse uniformly inside the diffusion chamber 2.

A sample stage 31 is located inside the reaction chamber 3 for the placement of sample(s), on the surface of which precursors and plasma react to form a thin film. Pumping chamber 4 is sequentially connected to an exhaust trap 5, used to absorb excess precursors, and to a pumping system.

The plasma generation device can be an inductively coupled plasma generation device. For example, the device can be a coil 11. Plasma generation chamber 1 is made from high purity (>99%) Alumina or quartz, which can withstand the corrosion from most gases (including fluorides). Coil 11 surrounds the periphery of the plasma generation chamber 1. When a high frequency current is conducted through the coil 11, the plasma generation gas inside the plasma generation chamber 1 will generate plasma under suitable pressure.

In addition, coil 11 can be formed from a copper tube with outer diameter from 3 to 8 mm. Coil 11 formed from the copper tube can have 2-5 turns, with the distance between neighboring turns between 15-25 mm. Struts can be placed outside the coil 11 for adjusting the height of coil 11. The inner diameter of the plasma generation chamber can be between 40-100 mm.

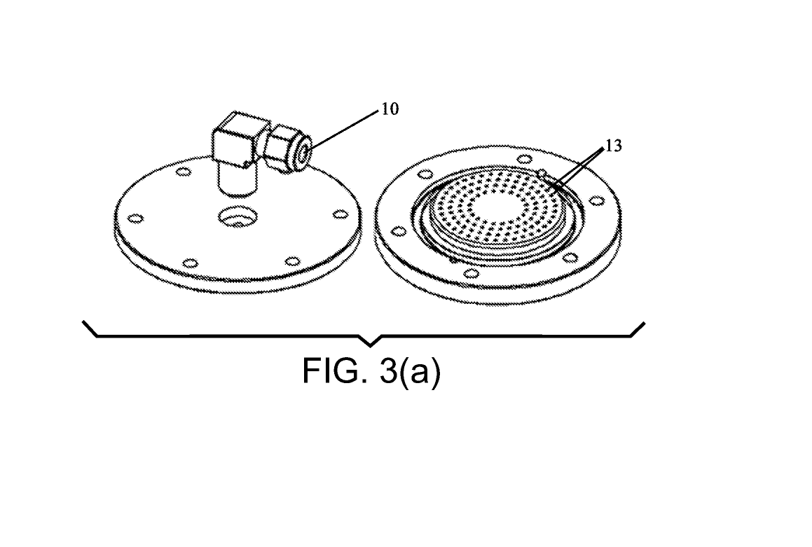

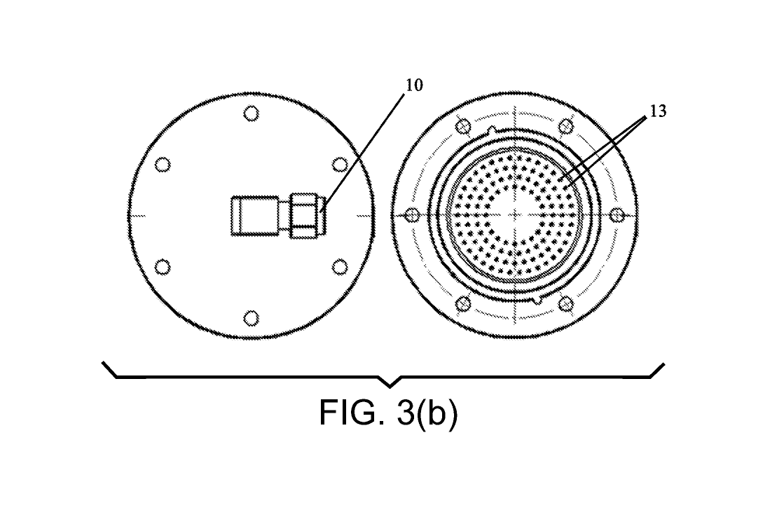

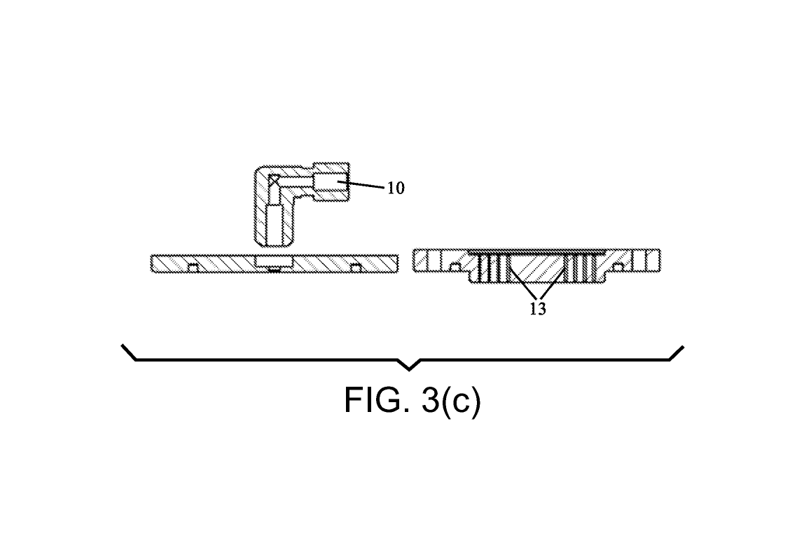

As shown in FIG. 3A to FIG. 3C, the plasma-enhanced atomic layer deposition equipment in this invention can also include the showerhead component, located inside the plasma generation chamber 1. The showerhead component contains multiple diffusion holes 13. The plasma generation gas inlet 10, diffusion holes 13, and the plasma generation chamber are fluidly connected. That is, the plasma generation gas coming from the plasma generation gas inlet 10 flows through diffusion holes 13, and enters the plasma generation chamber1, in a showering manner. The showering manner can lead to more uniform diffusion of the plasma. As shown in the figure, the showerhead component can be realized in the following manner: the plasma generation chamber 1 contains a top cover to seal off chamber 1. The top cover contains a through-hole that connects the plasma generation gas inlet 10 and the showerhead component, structurally adapted to the top cover.

In other words, the top cover, the showerhead component, and the plasma generation chamber 1 are combined (for example, fixed with 6 screws at the circumference), to form a tightly sealed structure. The top cover and the showerhead component are shaped into, but not limited to, e.g., a slab-shape. Other shapes are applicable as long as tight-seal and fluid-connectivity are guaranteed. In addition, the inner diameter of the plasma generation chamber 1 can be 2 to 12 mm. The inner diameter of multiple diffusion holes can be 0.2 to 3 mm. The seal between plasma generation chamber 1, the top cover, and the showerhead component can be rubber o-ring or oxygen-free copper gasket.

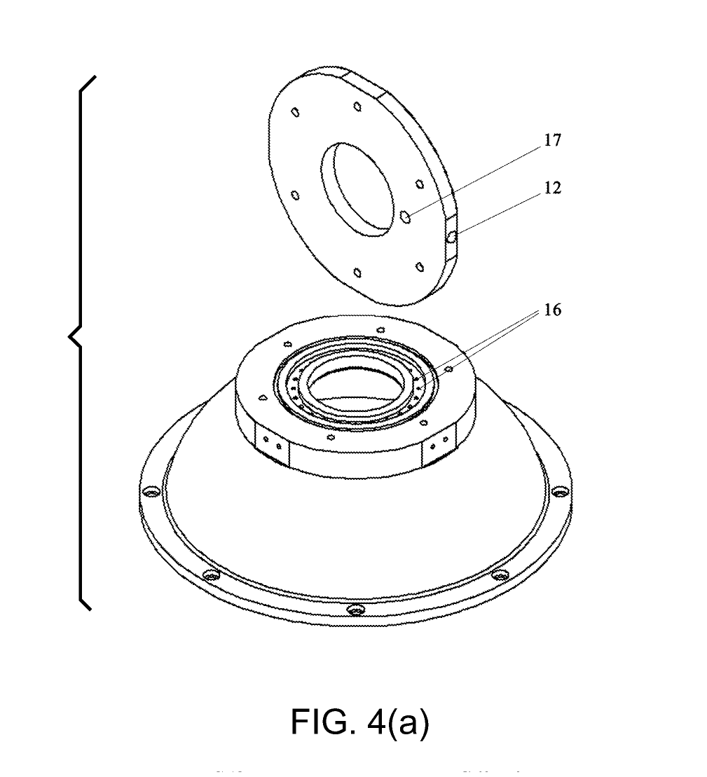

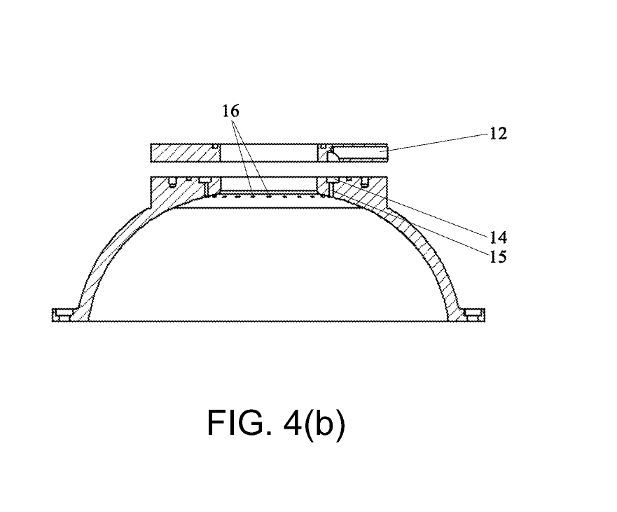

In one embodiment, the diffusion chamber 2 can be a uniquely shaped aluminum dome, in order for plasma and precursors to diffuse uniformly inside the diffusion chamber 2. As shown in FIGS. 4A and 4B, the specific structure is the cross-section of the diffusion chamber 2, which is symmetrical from left to right. Take either side as an example, to show that the cross-section is formed by smoothly joined arcs, one on top of the other. In addition, the curvature of the arc below is greater than the curvature of the arc above.

In one embodiment, the plasma-enhanced atomic layer deposition equipment can also include an annular multi-hole component located on the diffusion chamber 2. The annular multi-hole component contains multiple diffusion holes 16. Precursor inlet(s) 12, diffusion holes 16, and precursor inlet(s) 2 are fluidly connected. That is, precursors coming from the precursor inlet 12 go through diffusion holes 16 to enter the diffusion chamber 2, and then diffuse uniformly in the diffusion chamber 2, to further diffuse. The multi-hole component shown in FIGS. 4A and 4B can be realized in the following manner: a lid is located between the plasma generation chamber 1 and the diffusion chamber 2. A through-hole, for plasma to go through, is located in the middle of the lid. Precursor inlet 12 is located at the annular surface along the periphery of the lid.

Precursor inlet 12 is fluidly connected with precursor outlets which run through the lid. The annular component contains a through-hole, which allows plasma to go through, containing an annular hole 14, that runs through the outer surface of the component, and is fluidly connected with the precursor outlet 17, and contains multiple through-holes 15 that are fluidly connected with the annular hole 14. That is, precursor inlet 12, precursor outlet 17, annular hole 14, through-hole 15, and diffusion chamber 2 are fluidly connected.

In one embodiment, the inner diameter of the precursor inlet 12 can be 2-12 mm. The inner diameter of diffusion holes 16 can be 0.2-4 mm. The connection between the plasma generation chamber 1, the lid, the annular multi-hole component, and the diffusion chamber 2 can be connected and sealed with rubber o-rings or oxygen-free copper gaskets.

In one embodiment, the distance d between the top surface of the sample stage 31 and the ceiling of the reaction chamber 3 is greater than 200 mm. This distance guarantees that the plasma reaching the sample stage 31 provides necessary reaction energy, and in the meantime, prevents any negative side-effect, such as etching and oxidation of the sample. In the reaction process, precursors are carried by carrier gas into the diffusion chamber 2. After going through the diffusion chamber 2, the distribution and flow of plasma and precursors diffuse uniformly. Afterwards, plasma and precursors enter the reaction chamber 3, and then precursors adsorb on the surface of the sample, to react to form a thin film. The reaction energy is provided by the plasma.

In one embodiment, the plasma enhanced atomic layer deposition equipment can also include a heating element 33 for heating the sample stage 31. Electrode wires of the heating element 33 go through a tube with vacuum flanges 34 on both sides, so as to guarantee the vacuum tight seal of the reaction chamber 3, when the wires are connected to the outside, and also to prevent the arcing between electrodes during plasma generation.

The heating element 33 is widely available in the market, the specific structure of which does not need further explanation here. The energy needed for the reaction can come either from the plasma or from the heat from the heating element 33. Energy can also simultaneously come from those two sources.

In one embodiment, the plasma-enhanced atomic layer deposition equipment can also include a sample tray 32, which can be made from pure nickel, and the thickness of which can be 2-5 mm. Sample tray 32 has two usages: one is for samples to be put on top of it, for ease of being transported into the reaction chamber 3, and the other is to prevent the release of impurities from the stainless steel material, from which the sample stage 31 is made, at high temperature and through interaction with plasma.

Alternatively, samples can be placed directly onto the sample stage 31 without using the sample tray 32. In addition, sample tray 32 can be fixated onto sample stage 31 through clamping slots. In addition, the diameter of sample tray 32 can be slightly larger than that of sample stage 31, so that when sample tray 32 is put onto sample stage 31 upside down, the sample tray 32 will not slip. In addition, the inner diameter of reaction chamber 3 can be 150 to 500 mm. Sample stage 31 can be made from stainless steel or pure nickel, the diameter of which can be 100-300 mm. The ratio of the diameter of sample stage 31 and the inner diameter of reaction chamber 3 can be between 1:1.2 and 1:2, in order for gas to flow smoothly throughout the entire equipment.

In addition, the vacuum seal between diffusion chamber 2 and reaction chamber 3 can be rubber o-ring or oxygen-free copper gasket. In one embodiment, pumping chamber 4 can be conic in shape. Pumping chamber 4, reaction chamber 3, diffusion chamber 2, and plasma generation chamber 1, together, form a spindle-like chamber to enable uniform flow of plasma and precursor inside such a chamber. It is to be understood that pumping chamber 4, reaction chamber 3, diffusion chamber 2, and plasma generation chamber 1 can be connected, for example, with screws and can be sealed with rubber o-rings or oxygen-free copper gaskets. Of course, because pumping chamber 4 is located below sample stage 31, there is no strict requirement on its shape, which can take on other arbitrary shapes, other than conic shape.

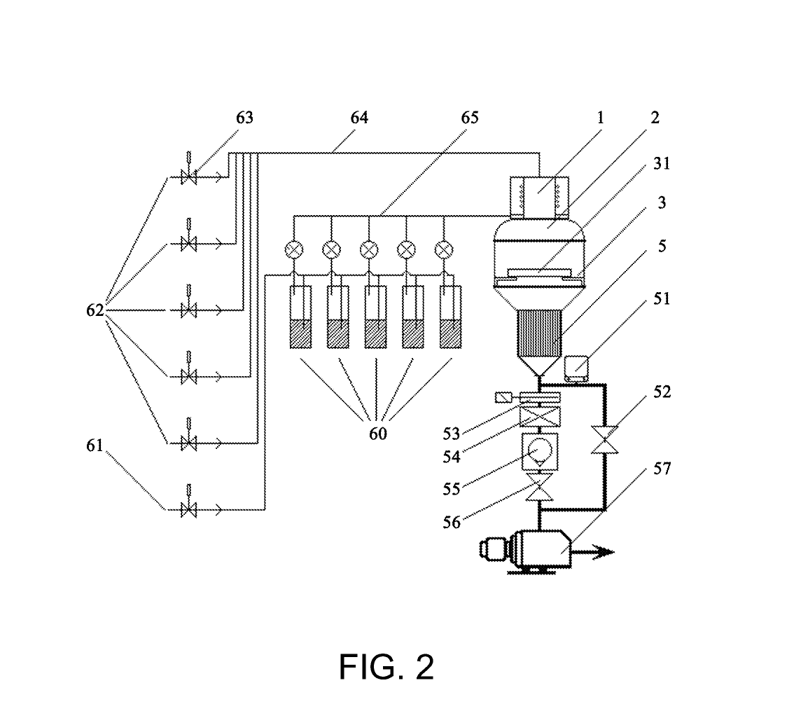

Exhaust trap 5 is used to absorb excess precursors, wherein channels can remove relatively large sized particles to clean up the exhaust, so as to protect pumping system down-stream. The pumping system can include vacuum gauge 51, by-pass valve 52, throttle valve 53, high vacuum valve 54, turbo-molecular pump 55, foreline valve 56, and mechanical pump 57 (for the connection sequence and working principles refer to FIG. 2). Before the deposition process, the pumping system evacuates the entire chamber. After the start of the deposition process, the pumping system pumps out excess precursors and by-products from the reaction.

Detailed procedure is: when evacuating the chamber, first open the by-pass valve 52, to evacuate the chamber to rough vacuum level, with mechanical pump 57, and then turn on turbo-molecular pump 55, open high vacuum valve 54 and foreline valve 56, and at the same time, close the bypass valve 52, to evacuate the chamber with turbo-molecular pump 55, to high vacuum level. In addition, the system is equipped with throttle valve 53, to control needed vacuum level.

In addition, the adjustment range for the vacuum level can be 0.1 to 1000 Pa. As shown in FIG. 2, the operating procedure for the plasma-enhanced atomic layer deposition equipment includes the following steps:

1. Multiple (for example, five, as shown in FIG. 2) precursors 60, carried by carrier gas 61, enter diffusion chamber 2, through precursor inlet 65. In one embodiment, the on-and-off operation of the supply of each precursor 60 to diffusion chamber 2 can be controlled by each corresponding valve. In addition, other methods, such as heating and ultrasonic nebulization, can be used to assist the entry of precursors 60 into diffusion chamber 2.

2. Multiple (for example, five, as shown in FIG. 2) plasma generation gases 62 enter plasma generation chamber 1, through plasma generation gas inlet 64, of which mass flow controller 63 can be used to control the flow of each plasma generation gas 62. At this time, plasma is generated from plasma generation gas 62, under the influence of plasma generation device, upon the entry of proper amount of plasma generation gas 62 into the evacuated plasma generation chamber 1. In addition, the plasma generated diffuse towards diffusion chamber 2, and then uniformly diffuse in diffusion chamber 2.

3. Uniformly diffused precursors 60 and plasma enter reaction chamber 3 from diffusion chamber 2. Precursors 60 adsorb onto the surface of the sample placed on sample stage 31, located inside reaction chamber 3, and react to form needed thin film with energy provided by the plasma. When the number of precursors 60 is two, the first precursor first adsorbs onto the surface of the sample to be deposited on. Then, the second precursor adsorbs onto the surface of the sample, to be deposited on to react with the first precursor adsorbed to form a thin film.

When the number of precursors 60 is three, the second precursor remains adsorbed on the surface of the sample to be deposited on, in order for the third precursor to adsorb and react with it, to form a thin film. Plasma can be the second precursor to react directly with the a-priori adsorbed first precursor, to form a thin film.

4. Excess precursors and by-products after the completion of a reaction enter exhaust trap 5, through pumping chamber 4. After exhaust trap 5 removes materials in the exhaust that may damage the subsequent pumping system, cleaned exhaust goes to the atmosphere through the pumping system.

Based on the disclosed plasma-enhanced atomic layer equipment in this invention, a plasma-enhanced atomic layer deposition method is also herein disclosed. The method includes: under vacuum condition, uniformly distributing generated plasma and precursors on the surface of sample, precursors adsorb on the surface of sample to be deposited on, and react to form a thin film. In addition, the method also includes: heating the sample to be deposited on, to provide energy needed for precursors to react to form a thin film. In addition, the method can also include: removing excess precursors and by-products from the reaction.

The description above only represents some examples or embodiments, and is not intended for limiting the applicability of this invention. That is, any equivalent changes or modifications based on claims in this invention are also covered by this invention.

1. A plasma-enhanced atomic layer deposition apparatus, said apparatus comprising:
a plasma generation chamber;
a diffusion chamber;
a reaction chamber;
a pumping chamber;
wherein said plasma generation chamber, said diffusion chamber, said reaction chamber, and said pumping chamber are fluidly connected;
wherein said plasma generation chamber comprises a plasma generation gas inlet and a plasma generation device, which enables gas, coming from said plasma generation gas inlet, to generate plasma;
wherein a precursor inlet is located between said plasma generation chamber and said diffusion chamber;
wherein precursors coming from said precursor inlet and said generated plasma diffuse uniformly inside said diffusion chamber;
a sample stage;
wherein a substrate is disposed on said sample stage, which is located inside said reaction chamber;
an exhaust trap;
a pumping system;
wherein said pumping chamber is sequentially connected to said exhaust trap and said pumping system.

2. The plasma-enhanced atomic layer deposition apparatus as recited in claim 1, wherein said plasma generation device is an inductively coupled plasma generation device.

3. The plasma-enhanced atomic layer deposition apparatus as recited in claim 1, said apparatus comprises:
a showerhead component, located in said plasma generation chamber;
said showerhead component comprises multiple diffusion holes;
wherein said plasma generation gas inlet, said multiple diffusion holes, and said plasma generation chamber are fluidly connected.

4. The plasma-enhanced atomic layer deposition apparatus as recited in claim 1, said apparatus comprises:
an annular multi-hole component, located in said diffusion chamber;
said annular multi-hole component comprises multiple diffusion holes;
wherein said precursor inlet, said multiple diffusion holes, and said diffusion chamber are fluidly connected.

5. The plasma-enhanced atomic layer deposition apparatus as recited in claim 1, wherein vertical distance between top surface of said sample stage and ceiling of said reaction chamber is greater than 200 mm.

6. The plasma-enhanced atomic layer deposition apparatus as recited in claim 1, said apparatus comprises: a heating element for heating said sample stage.

7. The plasma-enhanced atomic layer deposition apparatus as recited in claim 1, said apparatus comprises: a sample tray.

8. The plasma-enhanced atomic layer deposition apparatus as recited in claim 1, wherein ratio of diameter of said sample stage to inner diameter of said reaction chamber is between 1:1.2 and 1:2.

9. The plasma-enhanced atomic layer deposition apparatus as recited in claim 1, wherein said diffusion chamber has a dome shape for said generated plasma and said precursors to diffuse uniformly.

10. The plasma-enhanced atomic layer deposition apparatus as recited in claim 1, wherein vacuum seal between said pumping chamber, said reaction chamber, said diffusion chamber, and said plasma generation chamber are realized with rubber o-rings or oxygen-free copper gaskets.

11. The plasma-enhanced atomic layer deposition apparatus as recited in claim 1, wherein said pumping system comprises a pumping speed adjustment device or a throttle valve.

12. The plasma-enhanced atomic layer deposition apparatus as recited in claim 1, said apparatus comprises: a vacuum gauge.

13. The plasma-enhanced atomic layer deposition apparatus as recited in claim 1, said apparatus comprises: a by-pass valve.

14. The plasma-enhanced atomic layer deposition apparatus as recited in claim 1, said apparatus comprises: a turbo-molecular pump.

15. The plasma-enhanced atomic layer deposition apparatus as recited in claim 1, said apparatus comprises: a foreline valve.

16. The plasma-enhanced atomic layer deposition apparatus as recited in claim 1, said apparatus comprises: a mechanical pump.

17. The plasma-enhanced atomic layer deposition apparatus as recited in claim 1, said apparatus comprises: a mass flow controller.

18. The plasma-enhanced atomic layer deposition apparatus as recited in claim 1, said apparatus comprises: a vacuum flange.

19. The plasma-enhanced atomic layer deposition apparatus as recited in claim 1, said apparatus comprises: a high-vacuum valve.

20. The plasma-enhanced atomic layer deposition apparatus as recited in claim 1, said apparatus comprises: a coil.
